(19) United States
(12) Patent Application Publication
(10) Pub. No.: US 2007/0249129 A1
(43) Pub. Date: Oct. 25, 2007

(54) STI stressor integration for minimal phosphoric exposure and divot-free topography

(75) Inventors: Mark D. Hall, Austin, TX (US); Peter J. Beckage, Austin, TX (US); John J. Hackenberg, Austin, TX (US); Toni D. Van Gompel, Austin, TX (US)

Correspondence Address: Fortkort & Houston P.C., Suite 500, 9442 M. Capital of Texas Highway, Austin, TX, 78759, US

(73) Assignee: Freescale Semiconductor, Inc.

(21) Appl. No.: 11/408,346

(22) Filed: Apr. 21, 2006

(51) Int. Cl. H01L 21/762

(52) U.S. Cl. 438/296; 438/424; 438/435

(57) ABSTRACT

A method for making a semiconductor device is provided herein. In accordance with the method, a semiconductor structure is provided which comprises an active semiconductor layer (224) disposed on a buried dielectric layer (222). A trench (229) is created in the semiconductor structure which exposes a portion of the buried dielectric layer. An oxide layer (250) is formed over the surfaces of the trench, and at least one stressor structure (254) is formed over the oxide layer.

### FIELD OF THE DISCLOSURE

The present disclosure relates generally to semiconductor devices, and more particularly to methods for forming shallow trench isolation (STI) stressor structures in MOSFET devices to enhance their performance.

### BACKGROUND OF THE DISCLOSURE

The use of silicon-on-insulator (SOI) wafers in making MOSFET devices has become common in the art. In an SOI wafer, a semiconductor layer is provided which is disposed over a buried oxide (BOX) layer. SOI MOSFET transistors offer improvements over bulk MOSFET transistors in terms of circuit speed, reductions in chip power consumption, and in channel-length scaling. These advantages arise at least in part from the decreased junction capacitance made possible by the presence in these devices of a dielectric layer under the active semiconductor region.

The use of a thin layer of strained silicon in the channel layer of MOSFET devices has also been found to improve the performance characteristics of these devices. The presence of strain in the channel layer causes the individual silicon atoms within that layer to be forced farther apart or closer together in their lattice structure than would be the case in the unstrained material. The larger or smaller lattice spacing results in a change in the electronic band structure of the device such that current carriers (i.e., electrons and holes) have higher mobilities within the channel layer, thereby resulting in higher currents in the transistor and faster circuit speeds.

The use of strained silicon in SOI MOSFETs combines the advantages of these two features. Thus, in SOI MOSFETs, the presence of a buried insulator can drastically reduce parasitic capacitance, while the use of a strained silicon channel in a MOSFET enhances the drive current of the device. However, the use of strained silicon channels in SOI MOSFETs offers additional advantages over the use of such channels in bulk MOSFETs. Thus, in bulk MOSFETs, strained silicon channels are typically formed on a thick layer of SiGe, so the source and drain junctions are formed within the SiGe layer. Since SiGe has a lower energy gap and higher dielectric constant, this leads to higher junction capacitances and junction leakage. By contrast, when a strained silicon channel is formed in an SOI structure, the increased junction capacitance and leakage associated with SiGe are mitigated by the SOI structure, and thus are less detrimental to transistor performance.

Despite the aforementioned advantages of strained SOI MOSFETs, the fabrication of these devices is beset by certain challenges. In particular, the processes currently used to fabricate these devices generate an unacceptably high number of defects, especially in the NMOS and PMOS regions of these devices.

There is thus a need in the art for a process which overcomes this problem. In particular, there is a need in the art for a method for generating strained SOI MOSFET devices that generates an acceptably low level of defects, especially in the NMOS and PMOS regions of these devices. This and other needs may be met by the methodologies disclosed herein.

### BRIEF DESCRIPTION OF THE DRAWINGS

FIG. 1 is an illustration of a step in a first prior art process for forming a thermally grown oxide liner in an SOI device;

FIG. 2 is an illustration of a step in a first prior art process for forming a thermally grown oxide liner in an SOI device;

FIG. 3 is an illustration of a step in a first prior art process for forming a thermally grown oxide liner in an SOI device;

FIG. 4 is an illustration of a step in a first prior art process for forming a thermally grown oxide liner in an SOI device;

FIG. 5 is an illustration of the occurrence of a bird's beak structure in a device made in accordance with the process of FIGS. 1-4;

FIG. 6 is an illustration of a step in a second prior art process for forming a thermally grown oxide liner in an SOI device;

FIG. 7 is an illustration of a step in a second prior art process for forming a thermally grown oxide liner in an SOI device;

FIG. 8 is an illustration of a step in a second prior art process for forming a thermally grown oxide liner in an SOI device;

FIG. 9 is an illustration of a step in a second prior art process for forming a thermally grown oxide liner in an SOI device;

FIG. 10 is an illustration of a step in a second prior art process for forming a thermally grown oxide liner in an SOI device;

FIG. 11 is an illustration of the voiding that can occur in a variation of the prior art process depicted in FIGS. 6-10;

FIG. 12 is an illustration of a step in a process for forming a thermally grown oxide liner in an SOI device in accordance with the teachings herein;

FIG. 13 is an illustration of a step in a process for forming a thermally grown oxide liner in an SOI device in accordance with the teachings herein;

FIG. 14 is an illustration of a step in a process for forming a thermally grown oxide liner in an SOI device in accordance with the teachings herein;

FIG. 15 is an illustration of a step in a process for forming a thermally grown oxide liner in an SOI device in accordance with the teachings herein;

FIG. 16 is an illustration of a step in a process for forming a thermally grown oxide liner in an SOI device in accordance with the teachings herein;

FIG. 17 is an illustration of a step in a process for forming a thermally grown oxide liner in an SOI device in accordance with the teachings herein; and

FIG. 18 is an illustration of the active regions of a MOSFET device which indicates the directions referred to in TABLE 1.

### DETAILED DESCRIPTION

In one aspect, a method for making a semiconductor device is provided. In accordance with the method, a substrate is provided which comprises an active semiconductor layer disposed on a buried dielectric layer. A trench is created in the substrate which exposes a portion of the buried dielectric layer, and a nitride layer is formed over the surfaces of the trench. The trench is backfilled with an oxide, and the oxide is subjected to densification at a maximum densification temperature of less than about 1200° C.

In another aspect, a method for making a semiconductor device is provided. In accordance with the method, a semiconductor structure is provided which comprises (a) an active semiconductor layer disposed on a buried dielectric layer, (a) a pad oxide layer disposed over the active semiconductor layer, and (c) a nitride mask disposed over the pad oxide layer. A trench is created in the substrate which extends through the nitride mask, the pad oxide layer and the active semiconductor layer, and which exposes a portion of the buried dielectric layer, and an oxide layer is formed over the surfaces of the trench. A layer of nitride is then formed in the trench, the trench is backfilled with an oxide, and the semiconductor structure is polished down to the pad oxide layer through chemical mechanical polishing (CMP).

These and other aspects of the present disclosure are described in greater detail below.

It has now been found that the incidence of defects in a strained SOI MOSFET device can be reduced through the use of chemical mechanical polishing (CMP) to remove the nitride caps in the NMOS and PMOS regions. This is preferably accomplished by utilizing the pad oxide layer of the device as a polish stop. Without wishing to be bound by theory, it is believed that the common practice of using a long chemical etch to remove the nitride caps during the formation of trench isolation structures in such devices can result in voiding in the vicinity of nitride stressors as a result of exposure of the stressors to the etch. This voiding can result in the presence within the isolation trench of gate material during gate stack processing, which in turn can result in short-circuiting of the device. By utilizing CMP rather than extended chemical etching to remove the nitride caps, the duration of the etch can be substantially reduced, thereby minimizing the opportunity for etching of the stressors (and subsequent voiding) to occur.

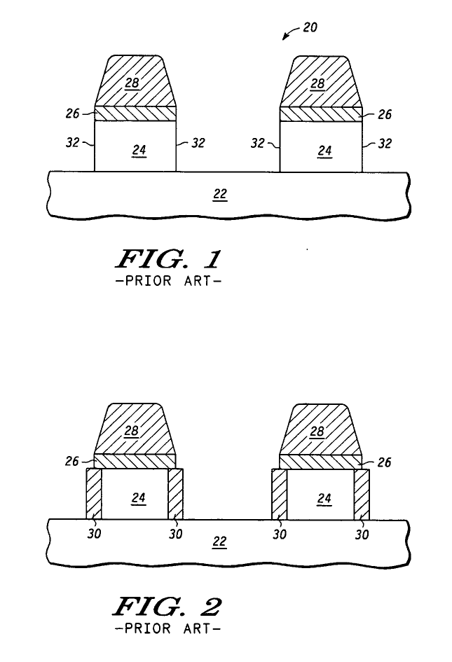

The methodologies described herein may be further appreciated by first considering the prior art process depicted in FIGS. 1-4. The structure 20 depicted in FIG. 1 is a common initial or intermediate structure that may be utilized in the fabrication of SOI devices. In this structure, a BOX layer 22 is disposed on a silicon wafer (not shown). A layer of active silicon 24 is disposed on the BOX layer 22, and a pad oxide layer 26 is disposed over the silicon layer 24. A layer of silicon nitride 28 is disposed over the pad oxide layer 26 to serve as a mask.

As seen in FIG. 1, the layers of active silicon 24 and pad oxide 26 have been appropriately patterned. This is typically achieved by using the silicon nitride layer 28 as a mask during the dry etching or reactive ion etching (RIE) of the silicon layer 24 and pad oxide layer 26. The silicon nitride mask 28 itself may be appropriately patterned through a suitable etching process that utilizes the pad oxide layer 26 as an etch stop layer.

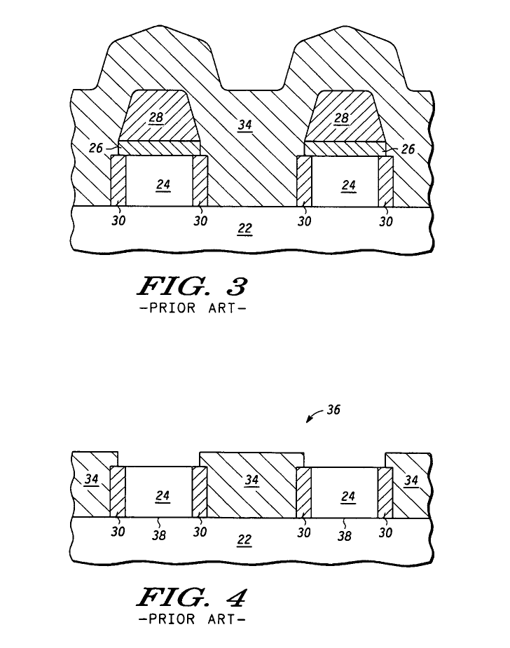

After the active silicon layer 24 has been patterned, an oxide liner 30 may be thermally grown on the vertical sidewalls 32 of the active silicon layer 24 as shown in FIG. 2. As shown in FIG. 3, after the liners 30 have been formed, a dielectric material 34 such as silicon dioxide is deposited to fill the gaps between the patterned active silicon structures 24, thereby forming shallow trench isolation (STI) structures between the active silicon structures 24. The dielectric material 34 may be deposited using a high density plasma chemical vapor deposition (HDP CVD) process. Subsequently, the nitride layer 28, the pad oxide layer 26, and a portion of the STI dielectric material 34 are removed by chemical mechanical polishing (CMP) and chemical etching to provide the SOI structure 36 depicted in FIG. 4.

It has been found that the prior art process depicted in FIGS. 1-4 results in a structure in which the liner 30 exerts compressive stress on the active silicon layer 24 at the interface 38 of the active silicon layer 24 and the BOX layer 22. Typically, the stress exerted is highest at the edges of the active silicon layer 24. The stress exerted on the active silicon layer 24 will typically be upward along the sidewalls of that layer and compressive towards the channel region.

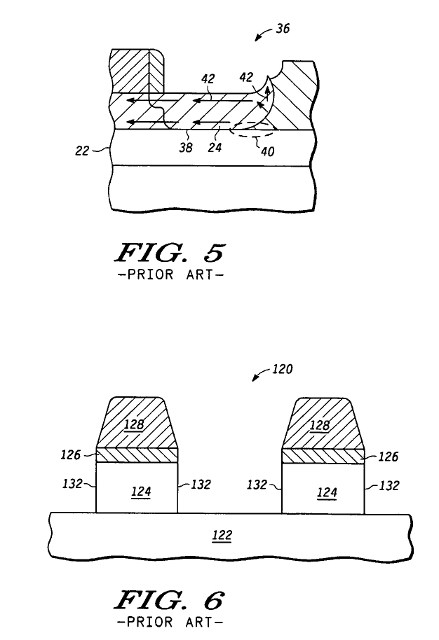

This stress is believed to be caused by the thermal growth process used to form the oxide liners 30. In particular, since the thermal growth of the oxide liners 30 occurs isotropically, including vertically along the sidewalls of the active silicon layer 24, as the oxide liners 30 are grown (see e.g., FIG. 2), the growth often extends into the BOX layer 22 at the interface of the active silicon layer 24 and the BOX layer 22. As shown in FIG. 5, this growth process may result in the lifting of the active silicon layer 24 at the liner 30 (and in particular, at the edge of the active silicon layer 24) and the associated formation of a “bird's beak” structure 40 of dielectric material that extends under the edge of the active silicon layer 24 at the interface 38. This bird's beak structure 40 applies strain to the active silicon layer 24, as illustrated by the arrows 42 in FIG. 5.

Various methods have been developed in the art to avoid the formation of bird's beak structures of the type depicted in FIG. 5. A typical example of such a method is depicted in FIGS. 6-10.

As shown in FIG. 6, in the method depicted therein, an initial structure 120 is provided which is similar to FIG. 1, and which may be formed in a similar manner. The structure 120 has a buried insulator layer 122 formed on a substrate (not shown). A patterned active silicon layer 124 is formed on the buried insulator layer 122. The patterned active silicon layer 124 has a pad oxide layer 126 formed thereon, and a silicon nitride mask layer 128 formed on the pad oxide layer 126.

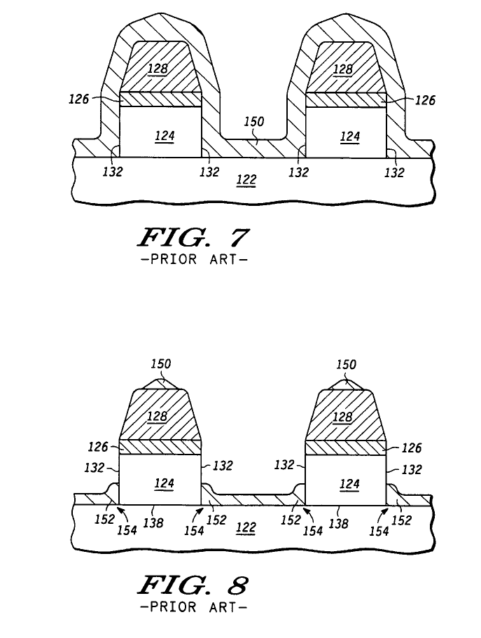

As shown in FIG. 7, a first conformal dielectric layer 150 comprising a material such as silicon nitride is formed on the initial structure 120 of FIG. 6. Part of the first dielectric layer 150 is then removed with an etching process, as shown in FIG. 8. The etching step is conducted so as to remove a portion of the first dielectric layer 150 in a way that sidewall portions 132 of the patterned active silicon layer 124 become exposed, and so that remaining portions 152 of the first dielectric layer 150 cover the comers 154 of the active trench where the patterned active silicon layer 124 interfaces with the buried dielectric layer 122. The remaining portions of the first dielectric layer 150 cover a lower portion of the sidewalls 132 of the patterned active silicon layer 124 and also cover the buried insulator layer 122, as shown in FIG. 8.

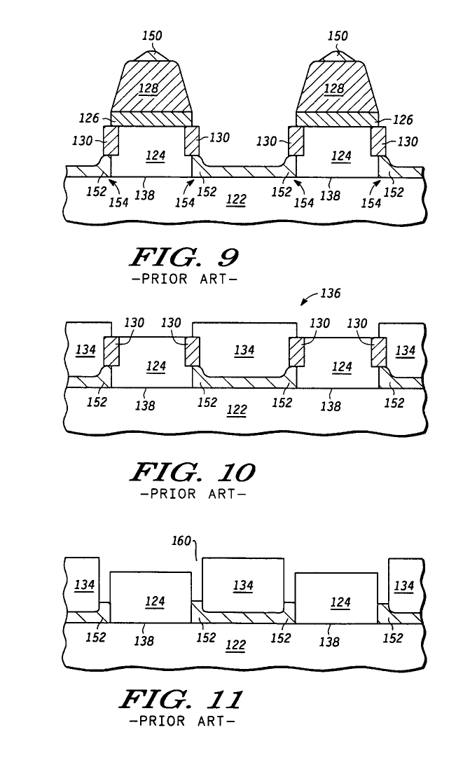

Next, as shown in FIG. 9, an oxide liner 130 is formed on the exposed portions of the active silicon layer 124, as through thermal oxidation. Since the remaining portions 152 of the first dielectric layer 150 are disposed in the comers 154 at the interface 138 of the active silicon layer 124 and the buried insulator layer 122, the oxide liner 130 is prevented from growing down to the interface 138 of the active silicon layer 124 and the buried insulator layer 122, hence reducing or preventing the formation of bird's beak structures of the type shown in FIG. 5. Referring to FIG. 10, the regions adjacent to the patterned active silicon layer 124 are then filled with a dielectric material 134 to form the STI, and the pad oxide layer 126 and silicon nitride mask layer 128 are removed by chemical mechanical polishing and chemical etching.

While the process depicted in FIGS. 6-10 may be effective in reducing the incidence of bird's beaking, it is undesirable in that complete removal of nitride from the sidewalls 132 while leaving it in the corners 154 is very difficult. Consequently, this process may be practiced with the omission of the steps depicted in FIGS. 8-9. In the modified process, the trench in the structure depicted in FIG. 7 is filled with a dielectric material 134 to form the STI, and the resulting structure is subjected to CMP using the silicon nitride mask layer 128 as a polish stop. The pad oxide layer 126 and silicon nitride mask layer 128 are then removed by chemical etching to yield the structure shown in FIG. 11. The chemical etch utilized in this step is typically a phosphoric acid etch, and frequently has a duration of 90 minutes or more. The device is then completed through subsequent processing steps.

The foregoing prior art processes are advantageous in that the presence of the conformal silicon nitride layer 150 on the sidewalls of the active silicon region 124 shields the bottom corners of that region from oxidation during the thermal oxidation process typically employed to form the STI structures, and hence prevents the occurrence of bird's beak structures in those regions. However, as previously noted, the approach depicted in FIGS. 6-10 is undesirable in that complete removal of nitride from the sidewalls 132 while leaving it in the comers 154 is very difficult. While the modified process depicted in FIG. 11 avoids these additional steps, it has its own shortcomings.

In particular, this approach relies on a long phosphoric etch process to remove the silicon nitride mask layer 128. It has now been found that this long etch can also remove a portion of the conformal silicon nitride layer 150 disposed on the sidewalls of the active silicon region 124, thereby creating a void 160 in this area. During subsequent processing, as during gate stack formation, polysilicon and other conductive materials can penetrate this void, thereby creating alternate current paths that can cause short-circuiting in the resulting device.

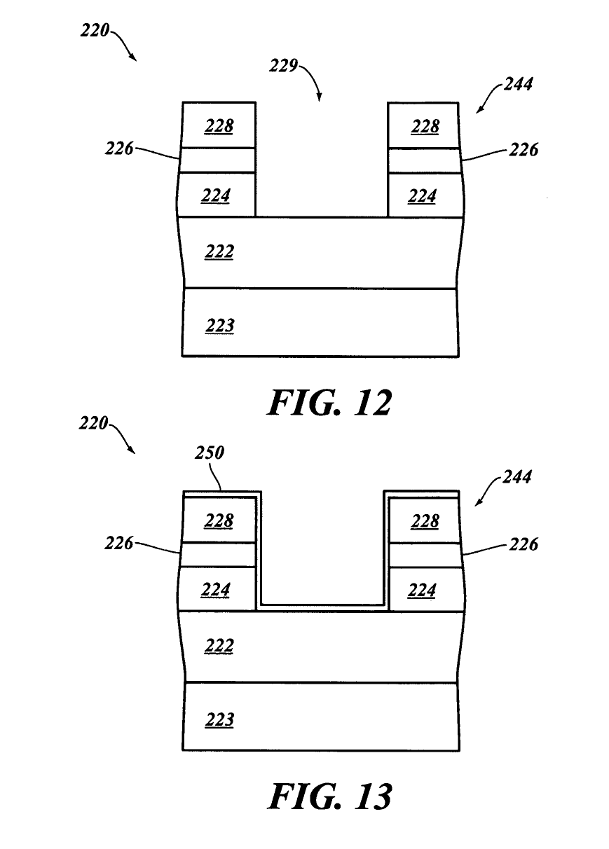

The methodology disclosed herein can be used to form nitride stressor structures in the NMOS and PMOS regions which minimize the incidence of such voiding. The manner in which stressor structures may be formed can be appreciated with respect to FIGS. 12-17, which illustrate a first non-limiting embodiment of a method for making an SOI MOSFET in accordance with the teachings herein.

With reference to FIG. 12, the process begins with an initial structure 220 which is similar in many respects to the structure of FIG. 1, and which comprises a carrier wafer 223, a buried oxide (BOX) layer 222, a patterned active silicon layer 224, a pad oxide layer 226, and a silicon nitride mask layer 228. A trench 229 has been created in the structure through suitable photomasking and etching. The trench 229 extends through the patterned silicon layer 224, the pad oxide layer 226 and the silicon nitride mask layer 228.

The carrier wafer 223 may be, for example, a silicon wafer, a germanium wafer, a SiGe wafer, or other suitable types of wafers or substrates as are known to the art. The BOX layer 222 is preferably silicon dioxide, but may also comprise other dielectric materials as are known to the art. The pad oxide layer 226 comprises an oxide which may be the same as, or different from, the oxide of the BOX layer 222, though in some embodiments the pad oxide layer 226 may be replaced by other dielectric materials.

As will be described in greater detail below, the pad oxide layer 226 serves as a CMP polish stop. The pad oxide layer 226 is preferably adapted to provide a suitable stress buffer to compensate for the differences in coefficients of thermal expansion in the active silicon layer 224 and the silicon nitride mask 228, and also serves as an adhesion promoter between the nitride mask 228 and the active silicon layer 224. Typically, the pad oxide layer has a thickness of at least about 200 Å, preferably, the pad oxide layer has a thickness of at least about 300 Å, more preferably, the pad oxide layer has a thickness of at least about 400 Å, and most preferably, the pad oxide layer has a thickness of at least about 500 Å.

The pad oxide layer 226 also protects silicon layer 224 during any wet etching processes that may be used to remove any remaining portions of the silicon nitride mask layer 228 after polishing. This wet etching is typically conducted with phosphoric acid, which is known to etch silicon. Of course, on skilled in the art will appreciate that, in some cases, the need for such a wet etch may be eliminated altogether.

The active silicon layer 224 is the layer in which devices such as transistors will be built. It will be appreciated that, in some embodiments, the active silicon layer 224 may actually include a plurality of layers and/or a plurality of materials. For example, the active silicon layer 224 may be (but is not necessarily limited to) epitaxially grown silicon, epitaxially grown SiGe, or combinations thereof. In other embodiments, other semiconductor materials, such as, for example, Ge or SiGe, may be substituted for silicon in this layer.

In the particular structure 220 depicted in FIG. 12, the patterned active silicon layer 224 has a cover layer 244 disposed thereon which, in this example, comprises a pad oxide layer 226 which is formed on the patterned active silicon layer 224, and a silicon nitride mask layer 228 which is formed on the pad oxide layer 226. In other embodiments, the cover layer 244 may contain additional layers.

Referring now to FIG. 13, an oxide liner 250 is formed on the exposed portions of the patterned active silicon layer 224, typically to a thickness of about 80 Å at the bottom of the trench (due to the anisotropy of the deposition process, this results in a liner thickness of about 40 Å on the sidewalls of the trench). Preferably, the oxide liner 250 is formed through plasma enhanced chemical vapor deposition (PECVD) or high density plasma (HDP) deposition.

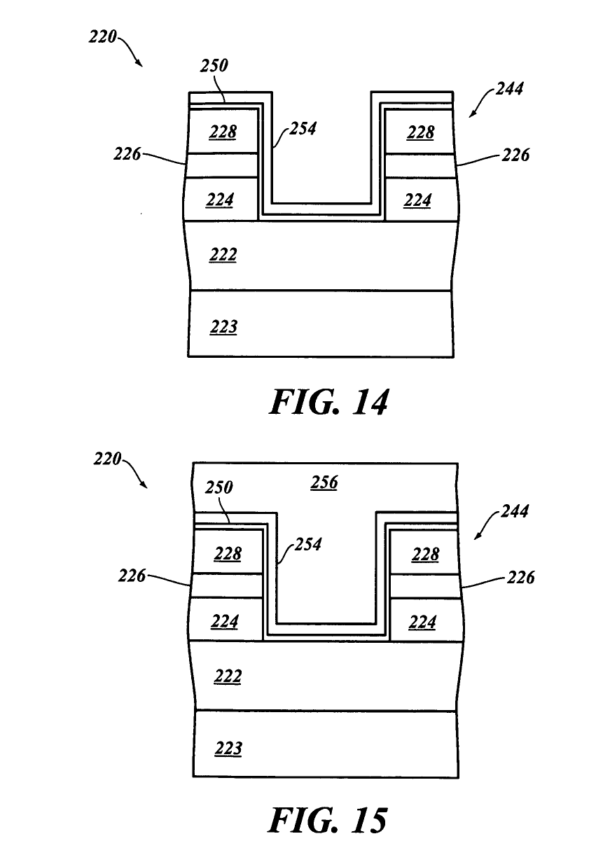

Referring now to FIG. 14, a layer of nitride 254 is then deposited over the oxide liner 250. Preferably, this is accomplished through thermal deposition in a furnace, though in some embodiments, the layer of nitride 254 may be deposited via plasma enhanced chemical vapor deposition (PECVD), via a high density plasma (HDP) process, or through other suitable means. The layer of nitride 254 is typically deposited to a thickness of about 50 Å to about 800 Å, preferably to a thickness of about 100 Å to about 600 Å, more preferably to a thickness of about 100 Å to about 300 Å, and most preferably to a thickness of about 200 Å. In some embodiments, the nitride layer 254, acting as a stressor material, may be patterned and etched on certain device types as needed through the use of suitable photolithographic techniques.

Referring now to FIG. 15, a trench fill oxide 256 is then formed over the structure. The trench fill oxide 256 is preferably a conformal layer. In a preferred process of forming the trench fill oxide 256, a high density plasma chemical vapor deposition (HDP CVD) process is used. However, other processes for forming the trench fill oxide 256 may also be used. The trench fill oxide 256 is preferably a dielectric material such as silicon dioxide.

After deposition or formation of the trench fill oxide 256, the structure may be subjected to one or more thermal cycles. The thermal cycles preferably include densification (the process of subjecting the trench fill oxide 256 to a high temperature, typically within the range of 950° C. to 1200° C., to increase its density and/or improve its dielectric properties), and later in the process sequence, the thermal cycles may also include sacrificial oxidation, double gate oxidation (DGO), or triple gate oxidation (TGO).

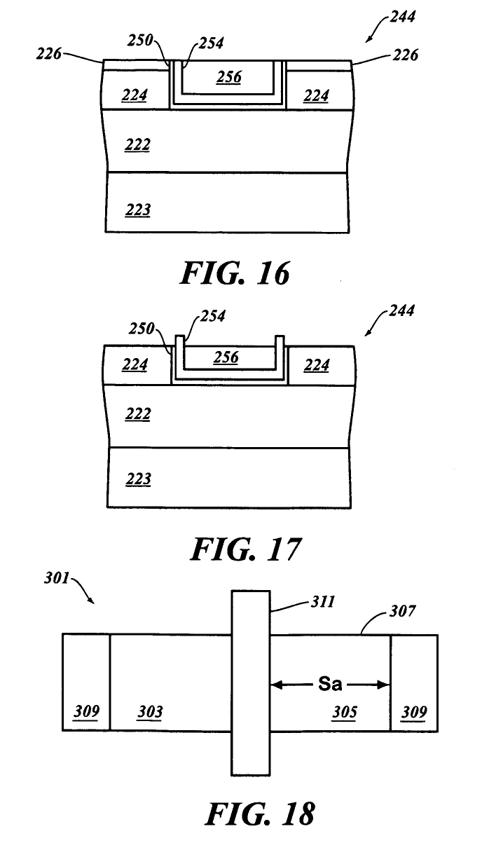

Referring now to FIG. 16, the structure is subjected to chemical mechanical polishing (CMP) using the pad oxide layer 226 as a polishing stop. An HF etch is then utilized to strip the remaining pad oxide layer 226 as shown in FIG. 17. This process also removes a portion of the trench fill oxide 256. The oxide liner 250 may be recessed slightly during this process, but the amount of the recess is small because of the small cavity that the etchant must penetrate, and may be compensated for, if desired, with a subsequent sacrificial oxidation. A short etch (wet or dry) may then be used to remove any remaining portion of the nitride layer 254 that extends above the surface of the trench fill oxide 256. The structure may then be completed through standard processing.

The improvements in MOSFET performance that are achievable with the methodologies described herein may be appreciated with respect to TABLE 1 below, which gives the piezoelectric resistance values for the NMOS and PMOS regions of a MOSFET device in response to compressive and tensile stress. The values in bold typeface are tension values, and the values in italicized typeface are compression values. The units of these values are percent improvement (as compared to an unstressed device) in the linear drive current of a device per 100 MPa of applied uniaxial stress. The channel direction (Sa), which is the direction the charge carriers are flowing from source to drain, is indicated in the device 301 shown in FIG. 18. The source 303, drain 305, active silicon layer 307, field oxide region 309 and poly gate 311 are also shown.

TABLE 1
Percentage Change in Drive Current
Per 100 MPa of Uniaxial Stress

| Channel | | Channel | Channel | Width | Width | Vertical |
|---|---|---|---|---|---|---|
| Direc- | | Stress | Stress | Stress | Stress | Stress |
| tion | Device | (Bulk Si) | (SOI) | (Bulk Si) | (SOI) | (Bulk Si) |
| <110> | NMOS | 3.1 | 2.6 | 1.8 | 1.6 | −5.3 |
| <110> | PMOS | −7.2 | −8.6 | 6.6 | 5.9 | 0.1 |
| <100> | NMOS | 10.2 | 1.9 | −5.3 | 1.4 | −5.3 |
| <100> | PMOS | −0.7 | −2.3 | 0.1 | −3.9 | 0.1 |

It will be appreciated from the data set forth in TABLE 1 that the use of a compressive stressor structure provides the greatest improvement in drive current in the PMOS region of an SOI MOSFET device and when the stressor structure is aligned with the channel. This is so even though the use of compressive stressor structures slightly degrade the performance of the NMOS device, since the effect of the compressive stressor structure in the PMOS region is the dominant effect with respect to overall CMOS performance. Hence, the use of compressive stressor structures in both regions provides a substantial improvement in device performance. Of course, one skilled in the art will appreciate that the use of a compressive stress material could be used in the PMOS region in conjunction with the use of a tensile stress material in the NMOS region to optimize overall CMOS performance.

The data set forth in TABLE 1 also suggest a number of possible variations to the methodologies and structures described above. For example, rather than applying a stressor structure to both the PMOS and NMOS regions of a MOSFET device, it will be appreciated that suitable masking and/or etching techniques could be utilized to restrict the formation of the compressive stressor structures to only the PMOS region, or to selectively remove the compressive stressor structures from the NMOS region. Of course, in a given implementation, the increased process complication attendant to the additional masking and/or etching steps would have to be weighed against the improvement in device performance gained by this process.

The data in TABLE 1 also indicate that the improvement in device performance in the channel direction with a compressive stressor structure comes to some extent at the expense of drive current in the width direction. In some embodiments, it may be possible to minimize degradation in device performance in the width direction by minimizing the width of the compressive stressor structure. A similar result may be achieved by applying nitride or another tensile stressor structure in the width direction of a PMOS device, while applying polysilicon as a compressive stressor structure in the channel direction. Here, it is to be noted that such a multidirectional approach may not be necessary for the NMOS device, since the data indicates that a tensile stressor structure such as nitride would improve device performance in both the channel and width directions.

As previously noted, after deposition of the trench fill oxide, the device is preferably subjected to thermal cycling. The thermal cycling may include densification, which is typically conducted within the range of 900° C. to 1200° C. Preferably, the maximum temperature for densification is within the range of about 900° C. to about 1050° C. Most preferably, the maximum temperature for densification is within the range of about 900° C. to about 1000° C. The duration of exposure of the device to this peak densification temperature is typically at least 5 minutes, preferably at least about 10 minutes, more preferably within the range of about 10 minutes to about 40 minutes, and most preferably within the range of about 15 minutes to about 30 minutes.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for making a semiconductor device, comprising:
providing a semiconductor structure comprising (a) an active semiconductor layer disposed on a buried dielectric layer, (a) a pad oxide layer disposed over the active semiconductor layer, and (c) a nitride mask disposed over the pad oxide layer;
creating a trench in the substrate which extends through the nitride mask, the pad oxide layer and the active semiconductor layer, and which exposes a portion of the buried dielectric layer;
forming an oxide layer over the surfaces of the trench;
forming a layer of nitride over the oxide layer; and
polishing the semiconductor structure down to the pad oxide layer.

2. The method of claim 1, wherein the layer of nitride and the oxide layer are coextensive.

3. The method of claim 1, further comprising patterning the layer of nitride to define one or more stressors therein.

4. The method of claim 3, wherein the layer of nitride is patterned with an isotropic etch.

5. The method of claim 1, wherein the buried dielectric layer is a buried oxide (BOX) layer.

6. The method of claim 1, wherein the active semiconductor layer comprises single crystal silicon.

7. The method of claim 1, further comprising the step of backfilling the trench with an oxide.

8. The method of claim 7, further comprising:
subjecting the oxide to densification at a densification temperature within the range of 900° C. to 1000° C.

9. The method of claim 8, wherein the densification is characterized by a maximum densification temperature and a duration of exposure to the maximum densification temperature, and wherein the duration of exposure of the device to the maximum densification temperature is within the range of about 15 to about 30 minutes.

10. The method of claim 1, wherein the semiconductor device is a MOSFET, and wherein the trench is formed in an NMOS or PMOS region of the device.

11. The method of claim 1, further comprising:
removing the pad oxide layer with an etch.

12. The method of claim 11, wherein the structure is subjected to sacrificial oxidation after the etch.

13. The method of claim 1, wherein the layer of nitride is a conformal layer.

14. The method of claim 13, wherein the layer of nitride extends over the nitride mask.

15. The method of claim 13, wherein the trench exposes a portion of the active semiconductor layer, and wherein the layer of nitride extends over the surface of the active semiconductor layer exposed by the trench.

16. A method for making a semiconductor device, comprising:
providing a semiconductor structure comprising (a) an active semiconductor layer disposed on a buried dielectric layer, (a) a pad oxide layer disposed over the active semiconductor layer, and (c) a nitride mask disposed over the pad oxide layer;
creating a trench in the substrate which extends through the nitride mask, the pad oxide layer and the active semiconductor layer, and which exposes a portion of the buried dielectric layer;
forming an oxide layer over the surfaces of the trench;
forming a layer of nitride in the trench;
backfilling the trench with an oxide; and
polishing the semiconductor structure down to the pad oxide layer through chemical mechanical polishing.

17. The method of claim 16, wherein the semiconductor device is a MOSFET, and wherein the trench is formed in an NMOS or PMOS region of the device.

18. The method of claim 16, further comprising:
subjecting the trench oxide to densification at a maximum densification temperature within the range of 900° C. to 1200° C.

19. The method of claim 18, wherein the duration of exposure of the device to the maximum densification temperature is within the range of about 15 to about 30 minutes.

20. The method of claim 16, further comprising:
removing the pad oxide layer with an etch.
